(19) United States
(12) Patent Application Publication
(10) Pub. No.: US 2025/0060927 A1
(43) Pub. Date: Feb. 20, 2025

(54) SEAMLESS TILING

(71) Applicant: VueReal Inc., Waterloo (CA)

(72) Inventor: Gholamreza CHAJI, Kitchener (CA)

(73) Assignee: VueReal Inc., Waterloo, ON (CA)

(21) Appl. No.: 18/723,403

(22) PCT Filed: Dec. 23, 2022
(86) PCT No.: PCT/IB2022/062747

§ 371 Date: Jun. 21, 2024

Related U.S. Application Data
(60) Provisional application No. 63/293,473, filed on Dec. 23, 2021.

(51) Int. Cl. G06F 3/14; H10K 59/18

(52) U.S. Cl. CPC G06F 3/1446; H10K 59/18

(57) ABSTRACT

The present disclosure relates to tiling which is one approach to develop large area electronic systems such as displays and sensors. In particular, the invention discloses connecting an array of tiles, an array of pixels and distributing signals between pixels in row and column. In addition, the invention discloses alignment of tiles, differentiability of tiles, sharing pixel circuits between subpixels with different microdevices, and EM signals controlling switches and alignment on opposite surfaces.

### CROSS-REFERENCE TO RELATED APPLICATIONS

This application claims the benefit of, and priority to. U.S. Provisional Patent Application No. 63/293,473 filed Dec. 23, 2021, which is hereby incorporated by reference herein in its entirety.

### FIELD OF THE INVENTION

The present disclosure relates to tiling which is one approach to develop large area electronic systems such as displays and sensors. It also discloses methods to improve transparency in pixelated optoelectronic systems such as display and sensors.

### SUMMARY

According to one embodiment, the present invention relates to a method to create an optoelectronic system, the method comprising; connecting an array of tiles wherein each tile has a substrate and an array of pixels, distributing signals between pixels in row and column direction wherein each signal is connected to two pads on the opposite sides of the tile substrate and connecting pads between adjacent tiles by forming traces.

According to another embodiment, the present invention relates to a method to enable a seamless connection between adjacent tiles in a microdevice array, the method comprising; having a tile substrate with contacts on at least one side of tiles, aligning tiles with a small space defined on a toleration of alignment between adjacent tiles and depositing a connection layer to connect signals between the tiles.

According to another embodiment, the present invention relates to a method to enable a seamless connection between adjacent tiles in a microdevice array, the method comprising; having tiles connected together in a system wherein tiles at sides or comers are differentiable from tiles in a middle and having the side and the corner tiles have blocks to generate signals or pass signals to the other tiles.

According to another embodiment, the present invention relates to an optoelectronic system the system comprising; an array of tiles integrated on a system substrate wherein each tile has a substrate and an array of pixels and wherein further signals are distributed in the row and column directions, each signal being connected to two pads on opposite sides of the tile substrate and the pads between two adjacent tiles are connected.

According to another embodiment, the present invention relates to a method to increase transparency of optoelectronic system comprising of an array of pixels, the method comprising; having microdevice systems with backplanes providing pixel circuits controlling microdevices and provide signals to the microdevice to enable its output or functions, sharing pixel circuits between subpixels with different microdevices or adjacent pixels, using switches to share the pixel circuits between microdevices, and controlling the switches by EM signals.

According to another embodiment, the present invention relates to a highly transparent optoelectronic system the system comprising; an array of pixels, each pixel having a pixel circuit, at least one optoelectronic microdevice, distribution of signals in column and row directions wherein the signals program and adjust a pixel circuit functionality and the pixel circuit adjusts the functions of the microdevices, the pixel circuit being shared between at least two microdevices in sub pixels or adjacent pixels, switches sharing the pixel circuits between microdevices, and EM signals controlling the switches.

According to another embodiment, the present invention relates to a method to create an optoelectronic system, the method comprising, connecting a first substrate to another substrate with no visible line, at least from one edge, having pads on top of the first substrate and the other substrate, wherein the top surface is an active area, having other pads located at a bottom surface of the first substrate, and aligning and bonding pads in the two substrates on opposite surfaces of the corresponding substrate to form a tiling.

According to another embodiment, the present invention relates to a method to create an optoelectronic system, the method comprising, aligning at least two substrates and put together, having pads on one surface, and connecting at least two pads from the substrate adjacent to each other with a connector wherein the connector has a substrate and a conductive structure.

### BRIEF DESCRIPTION OF THE DRAWINGS

The foregoing and other advantages of the disclosure will become apparent upon reading the following detailed description and upon reference to the drawings.

FIG. 1 shows an embodiment where it reduces the connection between the tiles

FIG. 2A shows the tile substrate with contacts on at least one side of the tiles.

FIG. 2B shows an embodiment where the circuits are adjusted to accommodate the pads closer to the array.

FIG. 2C shows position of microdevices in the pixel area needs to be adjusted so that the position of microdevices across the tile array is consistent.

FIG. 3A shows tiles are aligned and put closer together with a small space.

FIG. 3B shows an embodiment, to extend the size of pads for each tile.

FIG. 3C shows an embodiment that highlights the connection between the pads of adjacent tiles.

FIG. 3D shows an optical layer covering the surface of the tiles and the substrate.

FIG. 4A highlights a block diagram of tiles connected together to form a complete system.

FIG. 4B shows examples where the tiles are the same for center and edge.

FIG. 5 shows an example of sharing the pixel circuits between subpixels with different microdevices.

FIG. 6A shows the pixels include circuits, microdevice area, and devices.

FIG. 6B shows another related example, where the control signals for sharing or connecting the circuits to the devices are being shared between two rows.

FIG. 6C shows an exemplary embodiment of placing the microdevice on top of the capacitance.

FIG. 7 shows an optoelectronic system that includes a substrate and an active area.

FIG. 8 shows an optoelectronic system with the pads on one surface.

While the present disclosure is susceptible to various modifications and alternative forms, specific embodiments or implementations that have been shown by way of an example in the drawings and will be described in detail herein. It should be understood, however, that the disclosure is not intended to be limited to the particular forms disclosed. Rather, the disclosure is to cover all modifications, equivalents, and alternatives falling within the spirit and scope of an invention as defined by the appended claims.

### DETAILED DESCRIPTION

In this description, the terms “device” and “micro device” are used interchangeably. However, it is clear to one skilled in the art that the embodiments described here are independent of the device size.

Tiling is one approach to develop large area electronic systems such as displays and sensors. The challenge with tiling is to reduce the space between the tiles to achieve higher resolution systems. The space is affected by the tile bezels, interconnects between the tiles, and the driving parts needed at the edge of each tile.

One embodiment is to connect the tiles and pass the signals to the tiles through the adjacent tiles. In this case, the number of signals can be very high. For example, if the signals are the control signals for rows (or columns) or data and sense signals for columns (Rows), there can be tens to hundreds of signals between adjacent tiles.

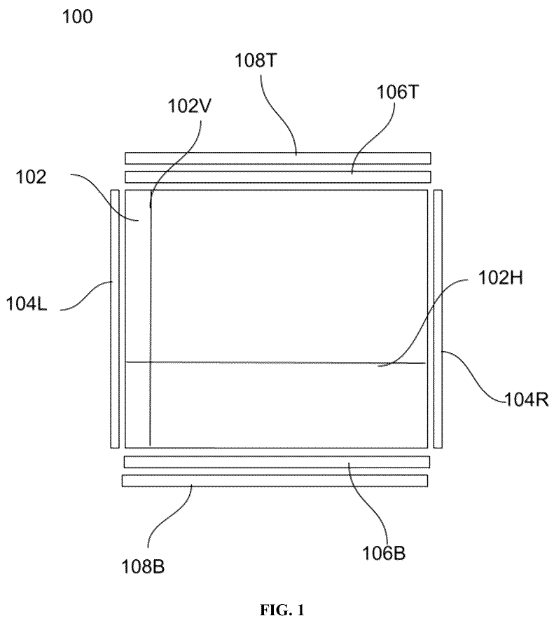

FIG. 1 shows a related embodiment 100 where it reduces the connection between the tiles. Here, array 102 has vertical side 102V and horizontal side 102H. In one case, multiplexing 106B and 106T can be used to reduce the number of signals. These blocks can be used for control signals at the horizontal or vertical lines. However, multiplexing, and other circuitry (108B and 108T) at the edge of the array can result in bezels that are wider than the pixel pitch. Other circuitry such as an address generator 104L, 104R can be used to select a row or column.

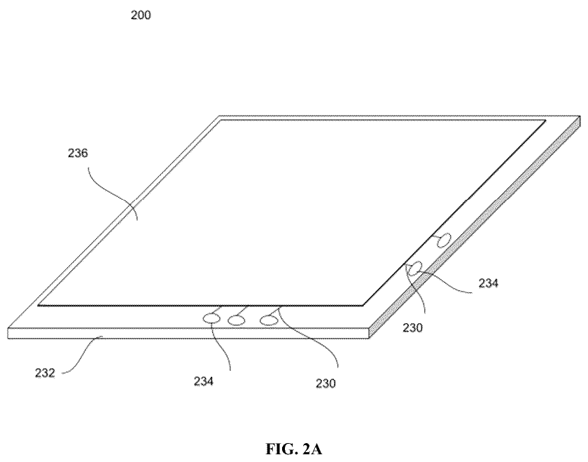

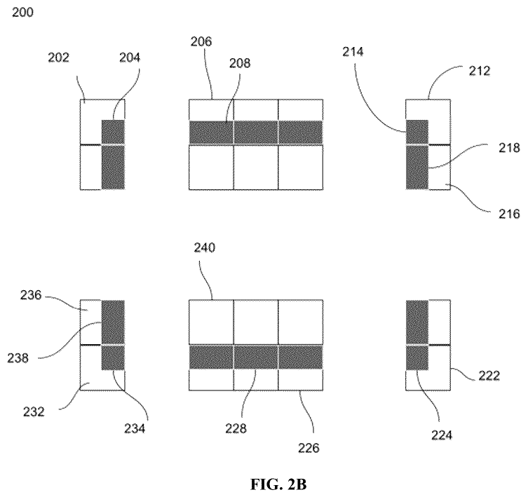

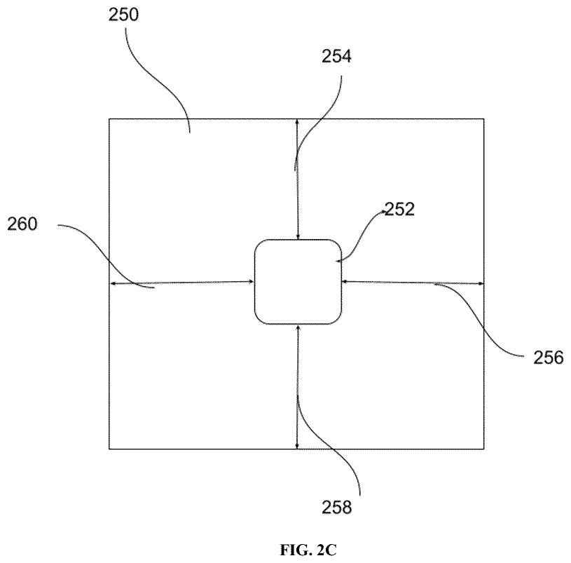

FIG. 2A shows in 200 the tile substrate 232 with contacts 234 on at least one side of the tiles. The pads 234 are connected to the array 236 by traces 230. To reduce the bezel around the array 236, the pads need to be moved close or inside the array 236.

FIG. 2B shows a related embodiment where the circuits are adjusted to accommodate the pads closer to the array. Here, the circuit in the pixels with pads is moved away from the pads toward the opposite direction. If the pads are on the left side of the array, the circuit 238 in the pixel 236 is moved closer to the right hand side of the pixel (this can be done with pixels in more than one column in the left side to create more space for pads). If the pads are on the right side of the array, the circuit 218 in the pixel 216 is moved closer to the left hand side of the pixel 216 (this can be done with pixels in more than one column in the right side to create more space for pads). If the pads are on the top side of the array, the circuit 208 in the pixel 206 is moved closer to the bottom hand side of the pixel 206 (this can be done with pixels in more than one column in the right side to create more space for pads). If the pads are on the bottom side of the array, the circuit 228 in the pixel 226 is moved closer to the top side 240 of the pixel 226 (this can be done with pixels in more than one column in the right side to create more space for pads). The pixels at the corners 202, 212, 222, and 232, the circuits 204, 214, 224 and 232 are moved the opposite direction.

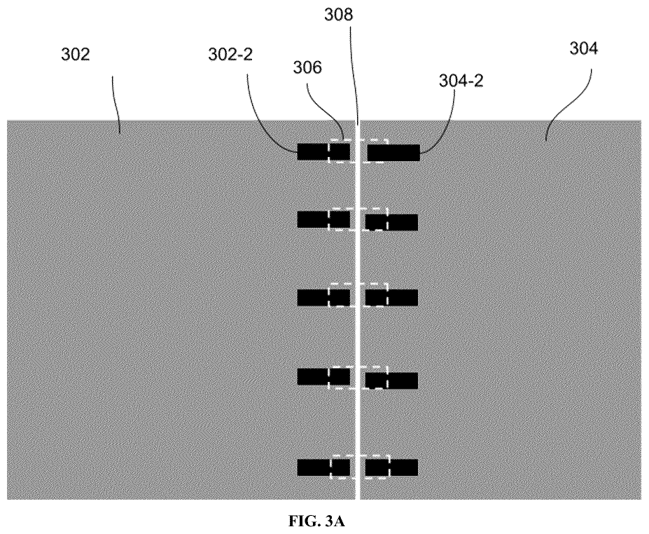

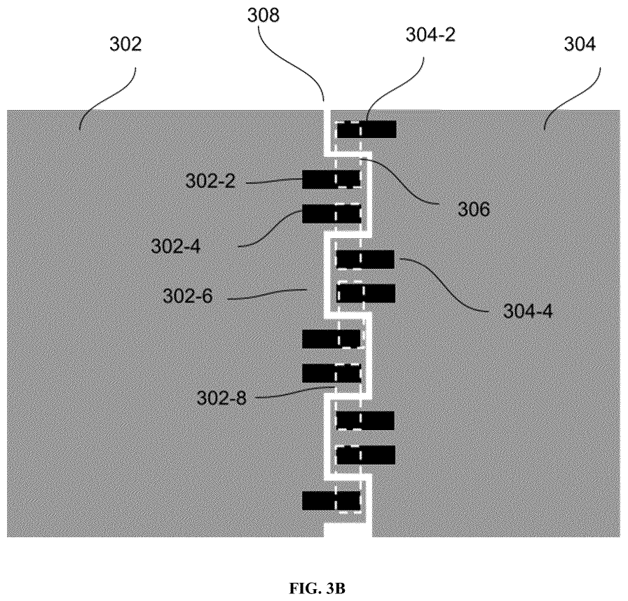

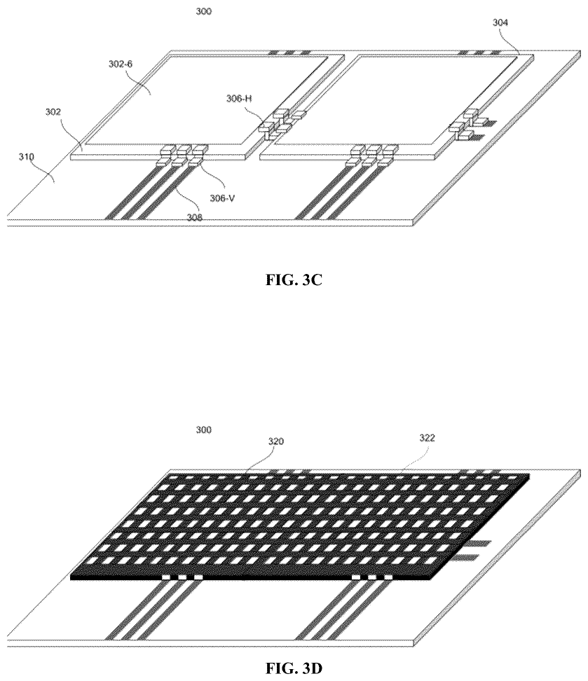

There are some errors in cutting the tiles and placing them adjacent together. As a result, the spacing between the microdevices on the edge of two adjacent tiles may be different from the pitch of the pixels. To reduce the visual impact on the image or captured data by the microdevice, the position of microdevices 252 (FIG. 2C) in the pixel area 250 (FIG. 2C) can be selected with consideration of the error so that the position of microdevices across the tile array is consistent. FIG. 2C shows an example of such a position Here, the microdevices are located in the proximity center of the pixel so the distance from the top 254 and bottom 258 and the distance from left 256 and right 260 are approximately or substantially the same. However, to accommodate different pixel designs as described in FIG. 3B in addition to alignment and cutting error, the microdevice 252 might be closer to one side. To increase the tolerance of image quality or captured data to the position of microdevices, a reflector 252 can be added under the microdevice that is larger than the microdevice 252 area.

FIG. 3 highlights embodiments that enable a seamless connection between adjacent tiles 302 and 304. Here, the tiles are aligned and put closer together with a small space 308. FIG. 3A shows a related example of the tile's connection. The space 308 is defined based on the toleration of alignment. A pixel pitch may comprise the space from one edge of the pixel to the other edge of the pixel in an array of pixels. The space 308 is larger than the aligned tolerance and smaller than the (2Wpixel-W302-W304) where the Wpixel is the pixel pitch, W302 is the width of pixel at the edge of tile 302 and W304 is the width of pixel at the edge of tile 304. The pads 302-2 and 304-2 are aligned to face each other. A connection layer 306 is deposited to connect the signals between the tiles 302 and 304. The space between tiles 308 can be filled with a filler layer to accommodate the connection between the tiles. For high resolution tiles, the pad size 302-2 can be small and therefore connection can be challenging

FIG. 3B shows another related embodiment, here to extend the size of pads 302-2, 302-4 304-2, and 304-4 for each tile 302 and 304, the edge of the tile has indentation 302-6 and the pads 302-2 and 302-4 are located on the areas 302-8 extending from the tile 302. The tiles are aligned so that the extension and indentation areas are offsetted so that the extended area of one tile fits in the indentation area of the other tile. The pads 302-2. and 304-2 (302-4, and 304-4) that need to be connected after the placement of the two tiles are adjacent. A connection 306 in almost the same direction of the edge is deposited to connect the two pads. The space between tiles 308 can be filed with a filler layer to accommodate the connection between the tiles. The edge of the tiles can be shampooed or cleaned prior to placing them together.

FIG. 3C shows a related embodiment 300 that highlights the connection between the pads of adjacent tiles. This can be applied to both cases of FIG. 3A and FIG. 3B. Here the tiles 302 and 304 are placed on a substrate 310. The substrate 310 can have traces 308 and some of pads for some of the tiles can be connected to these traces 308 through a connection 306-V. The traces 308 can be used to connect two adjacent tiles to each other or connect the tiles to a signal coming from the outside electronic system such as power, programming signals and data. In some related cases, the connection between the tiles is direct through a trace 306-H deposited to connect the adjacent pads In one related case, a planarization layer between the two tiles is formed to improve the connection between the adjacent tiles through trace deposition. In one related case, planarization layer is deposited after the tiles are placed on the substrate 310. In another related case, the edge of the tiles are covered (coated) with polymers. And the adjacent tiles are pushed toward each other so that the polymer fills the area between the two pads.

To minimize the effect of edges between the tiles, an optical layer 320 (in FIG. 3D) covers the surface of the tiles and the substrate 310. In case the optical layer is opaque, openings 322 (in FIG. 3D) are made to expose the microdevices.

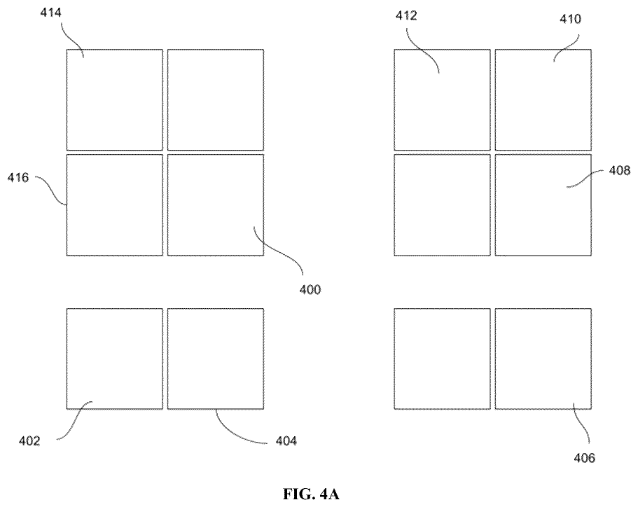

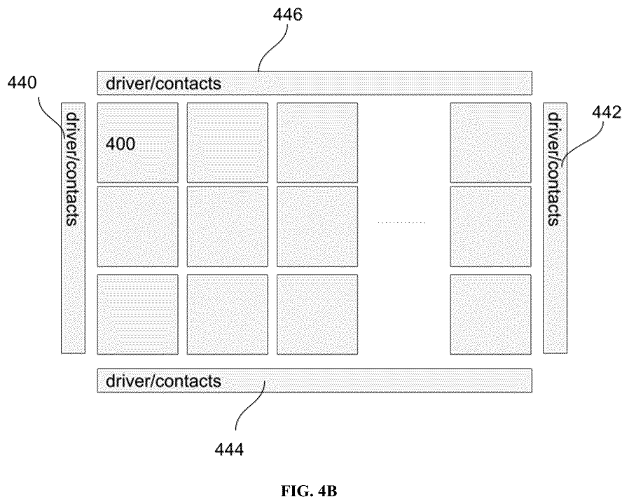

FIG. 4A highlights a block diagram of tiles (400 to 416: comprising 400, 402, 404, 406, 408, 410, 412, 414 and 416 connected together to form a complete system. The tiles at the sides or corners (402 to 416) can be differentiated from the tiles 400 in the middle. The tiles at the side and corners can have blocks to generate signals or pass signals to the other tiles.

FIG. 4B shows other related examples where the tiles 400 are the same for center and edge. To connect the tiles 400 to signals, there can be other blocks 440, 442, 444 and 446 at the edge where either generate the required signals or provide connections to connect the tiles to external signals. This block can be developed on the substrate 310 highlighted in FIG. 3C or 3D, or they can be bonded to the substrate.

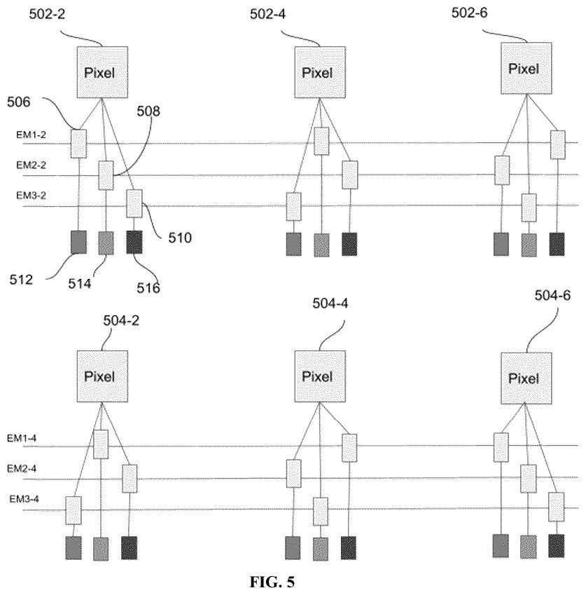

Another related advantage of microdevices systems is the possibility of developing a high transparent system (e.g., display or sensor array). These systems have backplanes that provide pixel circuits which control the microdevices and provide signals to the microdevice to enable its output or functions. And the microdevices are transferred and bonded to the circuits on the backplane. The system transparency is limited by the pixel components, traces, and microdevices itself. To reduce the area used by the pixel circuits 502-(2 to 6) and 504-(2 to 6) (in FIG. 5) are shared between adjacent sub pixels or pixels.

FIG. 5 shows an example of sharing the pixel circuits between subpixels with different microdevices 512, 514 and 516. To achieve this, switches 506, 508 and 510 are used to share the circuits between microdevices. The switches are controlled by signals EM1 to 3 (−2 to −4). The frame is divided into sub frames and during each sub frame the pixel is programed with data related to a microdevice and the switch related to that microdevice is activated to connect the circuit to the device. One challenge with this approach is the image quality can be compromised either for displays or capture images for sensors. To address this issue, at least two adjacent pixel circuits do not turn on the same devices during a sub frame. FIG. 5 demonstrates one example of this embodiment. Here the devices controlled by the same signals are different for adjacent pixels in the row or columns.

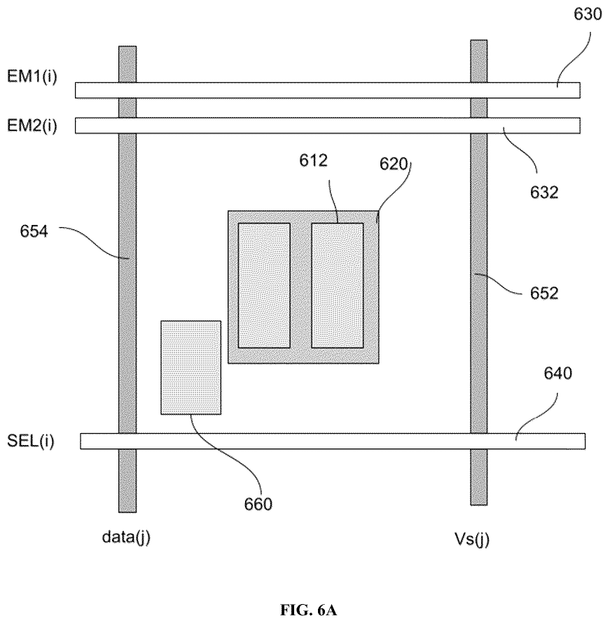

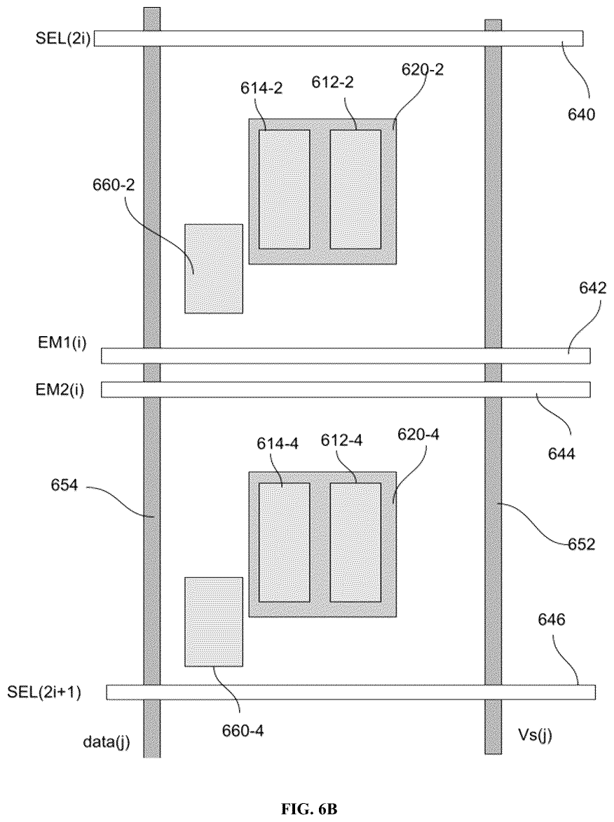

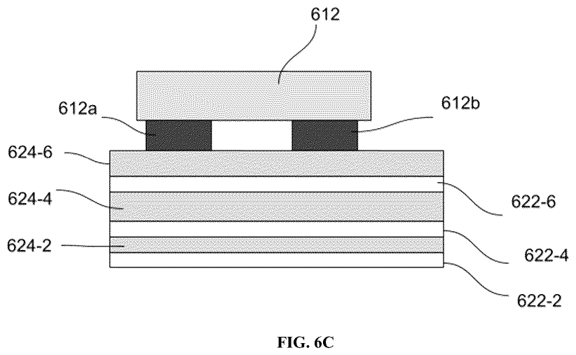

FIG. 6 shows an exemplary embodiment of the transparent pixel circuit. FIG. 6A shows one related example, the pixels include circuits 660, microdevice area 620, and devices 612. There are signal lines (data (j) SEL(i), vs(j)) distributed as rows or columns (654, 652, 630, 632, and 640). The signal in the rows can be a control signal EM(i) or EM(j) for enabling the pixel or connecting the pixel circuit to a device or other form of signals (SEL (i)). The signals in column format can provide data (data(j)), bias voltages or other forms of signals (vs(j)). The device area 620 can be the same area used to store the pixel signal in a capacitor. The capacitor is very opaque.

FIG. 6B shows another related embodiment, where the control signals EM1(i) and EM2(i) that control the connection of the circuits 660-2 to microdevices 614-2, 612-2 and circuits 660-4 to the devices 614-4 and 612-4 are shared between the two adjacent rows. There can be more than one control signal related to more than two microdevices in a pixel. The respective pixels include circuits 660-2, 660-4, microdevice areas 620-2 and 620-4, and devices 612-2, 614-2 and 612-4, 614-4. The sharing can be done with all or a selected number of control signals in adjacent rows. As a result, the two rows are activated or deactivated at the same time. The programming signals SEL(2i) SEL(2i+1) (640, 646) are different for each row. The programing signal SEL(2i) is activated first, the data(j) (654) value is stored or read from the pixel circuits 660-2. Then SEL (2i+1) is activated, and the data(j) is stored or read from pixel circuit 660-4. The EM1(i) signal or EM2(i) (642 or 644) signal is activated depending on the sub frame. The other signals vs(j) 652 can provide bias voltage to the pixels. For display application, the EM signals (EM1(i) or EM2(i)) are activated after SEL(2i) and SEL (2i+1) are activated and the circuits 660-2 and 660-4 are programmed. For reading the signals or sensor application, the EM signal is activated first and then the SEL signals are activated sequentially.

FIG. 6C shows an exemplary embodiment of placing the microdevice 612 on top of the capacitance. The capacitance is formed by two metal plates 622-2 and 622-4 and a dielectric 624-2 in between. To protect the capacitor another stack of layers 624-4, 622-6 and 624-6 are formed on top of the capacitor layers. In one case the protective layers are dielectric layer 624-4, metal layer 622-6 and another dielectric layer 624-6. The metal layer 622-6 can be coupled to the top plate of the capacitor to eliminate the shorting during placement of microdevices 612. There can be pads 612a and 612b to connect the microdevice to the circuits. The pads can be conductive or nonconductive.

Another embodiment relates to connecting tiles seamlessly in one direction. Here the pads are moved away from the active areas toward the edge that is not tiled.

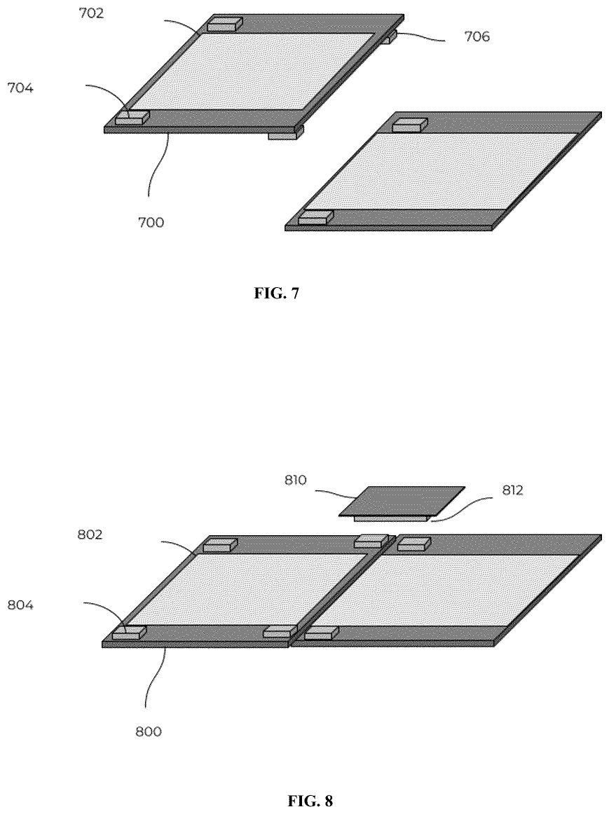

In one embodiment shown in FIG. 7, an optoelectronic system includes a substrate 700 and an active area 702. The substrate needs to be connected to another substrate (tiling) with no visible line, at least from one edge. This embodiment includes pads 704 on the top surface of substrate 700, where the top surface is where the active area is formed. In addition, the embodiment includes other pads 706 located at the bottom surface of the substrate. The pads in two substrates on opposite surfaces of the corresponding substrate are aligned and bonded to form tiling Other materials, such as a polymer based adhesive, can bond the edges of two substrates more securely. The adhesive can be UV curable, thermally curable, chemically curable or other curable materials. The pads pass signals between the tiles.

One invention relates to an optoelectronics system that includes a substrate 700, and an active area 702. The active area is away from at least one substrate edge. There are pads 704 and 706 on that edge of the substrate. The active area 702 is close to at least two substrate edges

In one related invention shown in FIG. 8, the pads 804 are on one surface (e.g., top). At least two substrates 800, with active areas 802, are aligned and moved close to each other with a predefined space. Here connector part 810 is used to connect at least two pads from the substrate adjacent to each other. The connector has a substrate and a conductive structure 812. The conductive structure can be a combination of conductive traces, bumps and bonding material. In another case, the adhesive material can be separated from the conductive traces or bumps. In another related structure, the conductive traces or bumps are the same. In another related structure, the conductive traces or bumps are the same as adhesive material.

### EMBODIMENTS

An embodiment of the invention discloses a method to create an optoelectronic system, the method comprising, connecting an array of tiles wherein each tile has a substrate and an array of pixels, distributing signals between pixels in row and column direction wherein each signal is connected to two pads on the opposite sides of the tile substrate and connecting pads between adjacent tiles by forming traces.

The embodiment further discloses that the tiles are assembled on a system substrate and wherein a bezel in the tile is reduced by moving the pads into a pixel area. Here the traces connect the pads of adjacent tiles through traces in the system substrate. Also, the traces connect the tiles to the signals through traces on the system substrate.

Another embodiment of the invention discloses a highly transparent optoelectronic system the system comprising, an array of pixels, each pixel having a pixel circuit, at least one optoelectronic microdevice, distribution of signals in column and row directions wherein the signals program and adjust a pixel circuit functionality and the pixel circuit adjusts the functions of the microdevices, the pixel circuit being shared between at least two microdevices in sub pixels or adjacent pixels, switches sharing the pixel circuits between microdevices and EM signals controlling the switches.

Here at least one EM signal between two adjacent rows is shared. Further, the adjacent pixels have different types of microdevices connected to the pixel circuits with the same EM signal. Here the microdevices can be microLED, OLED, sensors, and other types of optoelectronic devices. Additionally, the microdevices can be formed on a pixel storage capacitor and the pixel storage capacitor can be protected by a stack of dielectric, reflector, and dielectric layers.

While particular embodiments and applications of the present invention have been illustrated and described, it is to be understood that the invention is not limited to the precise construction and compositions disclosed herein and that various modifications, changes, and variations can be apparent from the foregoing descriptions without departing from the spirit and scope of the invention as defined in the appended claims.

1. A method to create an optoelectronic system, the method comprising:
connecting an array of tiles wherein each tile has a substrate and an array of pixels;
distributing signals between pixels in row and column direction wherein each signal is connected to two pads on the opposite sides of the tile substrate; and
connecting pads between adjacent tiles by forming traces.

2. The method of claim 1, wherein the tiles are assembled on a system substrate.

3. The method of claim 2, wherein the traces connect the pads of adjacent tiles through traces in the system substrate.

4. The method of claim 2, wherein the traces connect the tiles to the signals through traces on the system substrate.

5. The method of claim 1, wherein a bezel in the tile is reduced by moving the pads into a pixel area.

6. The method of claim 1, wherein a circuit in pixels with pads is moved away from the pads towards an opposite direction.

7. The method of claim 6, wherein if the pads are on a left side of the array, the circuit in the pixel is moved closer to a right hand side of the pixel.

8. The method of claim 6, wherein if the pads are on a right side of the array, the circuit in the pixel is moved closer to a left hand side of the pixel.

9. The method of claim 6, wherein if the pads are on a top side of the array, the circuit in the pixel is moved closer to a bottom side of the pixel.

10. The method of claim 6, wherein if the pads are on a bottom side of the array, the circuit in the pixel is moved closer to a top side of the pixel.

11. The method of claim 6, wherein pixels at corners and corresponding circuits are moved in the opposite direction.

12. The method of claim 6, wherein a position of microdevices in the pixel area is adjusted to be substantially in the center of the pixel area so that the position of microdevices across the array is consistent.

13. The method of claim 6, wherein to increase a tolerance of an image quality or captured data to the position of microdevices, a reflector is added under the microdevice that is larger than the microdevice area.

14. A method to enable a seamless connection between adjacent tiles in a microdevice array, the method comprising:
having a tile substrate with contacts on at least one side of tiles;
aligning tiles with a small space defined on a toleration of alignment between adjacent tiles; and
depositing a connection layer to connect signals between the tiles.

15-28. (canceled)

29. A method to enable a seamless connection between adjacent tiles in a microdevice array, the method comprising:
having tiles connected together in a system wherein tiles at sides or corners are differentiable from tiles in a middle; and having the side and the corner tiles have blocks to generate signals or pass signals to the other tiles.

30-32. (canceled)

33. An optoelectronic system the system comprising:
an array of tiles integrated on a system substrate wherein each tile has a substrate and an array of pixels and wherein further signals are distributed in the row and column directions;
each signal being connected to two pads on opposite sides of the tile substrate; and
the pads between two adjacent tiles are connected.

34-46. (canceled)

47. A method to increase transparency of optoelectronic system comprising of an array of pixels, the method comprising:
having microdevice systems with backplanes providing pixel circuits controlling microdevices and provide signals to the microdevice to enable its output or functions;
sharing pixel circuits between subpixels with different microdevices or adjacent pixels;
using switches to share the pixel circuits between microdevices; and
controlling the switches by EM signals.

48-66. (canceled)

67. A highly transparent optoelectronic system the system comprising:
an array of pixels;
each pixel having a pixel circuit;
at least one optoelectronic microdevice,
distribution of signals in column and row directions wherein the signals program and adjust a pixel circuit functionality and the pixel circuit adjusts the functions of the microdevices;
the pixel circuit being shared between at least two microdevices in sub pixels or adjacent pixels;
switches sharing the pixel circuits between microdevices; and
EM signals controlling the switches.

68-72. (canceled)

73. A method to create an optoelectronic system, the method comprising:
connecting a first substrate to another substrate with no visible line, at least from one edge;
having pads on top of the first substrate and the other substrate, wherein the top surface is an active area;
having other pads located at a bottom surface of the first substrate; and
aligning and bonding pads in the two substrates on opposite surfaces of the corresponding substrate to form a tiling.

74-76. (canceled)

77. A method to create an optoelectronic system, the method comprising:
aligning at least two substrates and moving the two substrates close to each other with a predefined space;
having pads on one surface; and
connecting at least two pads from the substrate adjacent to each other with a connector wherein the connector has a substrate and a conductive structure.

78-81. (canceled)
